(19) United States
(12) Patent Application Publication
(10) Pub. No.: US 2023/0112479 A1
(43) Pub. Date: Apr. 13, 2023

(54) PHOTODIODE

(71) Applicant: TYNTEK CORPORATION, Miaoli County (TW)

(72) Inventors: SHIH-KANG CHEN, MIAOLI COUNTY (TW); CHIH-YANG CHANG, MIAOLI COUNTY (TW); CHENG-YI HSU, MIAOLI COUNTY (TW)

(21) Appl. No.: 17/499,029

(22) Filed: Oct. 12, 2021

(51) Int. Cl. H01L 31/0216; H01L 31/109; H01L 31/0224

(52) U.S. Cl. CPC H01L 31/02161; H01L 31/109; H01L 31/0224

(57) ABSTRACT

The present invention provides a photodiode, which includes: a light absorption substrate, a first electrode portion, a second electrode portion, an antireflection layer, and a distributed Bragg reflection layer. The antireflection layer is arranged to receive light to get into the light absorption substrate. The antireflection layer is arranged to receive light to get into the light absorption substrate, and the distributed Bragg reflection layer is arranged to reflect light transmitting through the light absorption substrate to exit from the light absorption substrate back to the light absorption substrate, in order to enhance the photocurrent and the spectrum sensitivity of the photodiode.

### FIELD OF THE INVENTION

The present invention relates to a photodiode, and more particular to a photodiode that has a surface including a distributed Bragg reflector layer.

### BACKGROUND OF THE INVENTION

A photodiode is a semiconductor device that converts an optical signal into an electrical signal, and is commonly used in detecting visible light, infrared light, and ultraviolet light. Some LIDAR (light detection and ranging) systems include a receiver that makes use of a photodiode to receive light that was transmitted from the system and reflected by a target for subsequently converting into an electrical signal, so that the system may calculate a distance, a depth, or a range of the target by means of a time difference between light transmission and reception.

Some noninvasive blood oxygen concentration measurement devices include a light source and a photodiode of red light or infrared light. Since oxy-hemoglobin and deoxy-hemoglobin exhibit a greater difference in absorption rate in respect of red light and infrared light. Blood oxygen concentration can be calculated by having red light or infrared light penetrating through skin tissues and blood vessels and inspecting variation of intensity of the reflected light. Thus, the sensitivity of a photodiode in the wavebands of red light and infrared light is a key factor for accuracy of measurement of blood oxygen concentration.

When light enters a photodiode, photons are absorbed in a depletion zone of the photodiode for excitation and generation of electron-hole pairs. Such carriers drift and diffuse to generate a photocurrent. However, a portion of the light may not be absorbed and will transmit through and leave from the photodiode so as not to generate a response. Known photodiodes have relatively weak photocurrent and spectrum sensitivity for the infrared waveband, and are thus imperfect for applications in measurement of blood oxygen concentration. Further improvements are necessary.

### SUMMARY OF THE INVENTION

Thus, the present invention aims to provide a photodiode that alleviates and overcomes the deficiencies of the prior art and improve industrial uses thereof.

To achieve the above objective, the technical solution adopted in the present invention is to provide a photodiode, which comprises: a light absorption substrate, the light absorption substrate comprising a top surface and a bottom surface that are opposite to each other, the light absorption substrate being comprising a first semiconductor section, a second semiconductor section, and a third section, the first semiconductor section and the second semiconductor section being individually in contact with the third section, the first semiconductor section and the second semiconductor section being isolated from each other by the third section, the first semiconductor section and the second semiconductor section being of opposite conductivity types; an antireflection layer; and a distributed Bragg reflection layer, which is formed by stacking multiple layers of dielectric material films; wherein the antireflection layer is arranged on the top surface and in contact with the first semiconductor section, and the distributed Bragg reflection layer is arranged on the bottom surface to be in contact with the second semiconductor section, or the antireflection layer is arranged on the bottom surface and in contact with the second semiconductor section, and the distributed Bragg reflection layer is arranged on the top surface and in contact with the first semiconductor section; and wherein the antireflection layer is arranged to receive light to get into the light absorption substrate, and the distributed Bragg reflection layer is arranged to reflect light that transmits through the light absorption substrate to exit from the light absorption substrate back to the light absorption substrate.

In an embodiment of the photodiode according to the present invention, the first semiconductor section is a p-type semiconductor, and the second semiconductor section is an n-type semiconductor.

In an embodiment of the photodiode according to the present invention, the first semiconductor section is an n-type semiconductor, and the second semiconductor section is a p-type semiconductor.

In an embodiment of the photodiode according to the present invention, the distributed Bragg reflection layer has a thickness of 2 μm to 30 μm.

In an embodiment of the photodiode according to the present invention, the antireflection layer comprises silicon nitride.

In an embodiment of the photodiode according to the present invention, the thickness of the distributed Bragg reflection layer is 3 μm.

The present invention provides a photodiode that includes a distributed Bragg reflection layer to reflect light that transmits through the light absorption substrate to exit from the light absorption substrate back into the light absorption substrate, so as to reduce optical loss and enhance photocurrent and spectrum sensitivity. In an embodiment, the distributed Bragg reflection layer 4 has a thickness of 2 μm to 30 μm, and reflection rate for an infrared waveband of 900 nm to 1000 nm may reach as high as 95% to 99%, so as to enhance the photocurrent and the spectrum sensitivity the photodiode for the infrared waveband, and thus overcoming the problems of the prior art photodiode having relatively weak photocurrent and spectrum sensitivity in the infrared waveband, and as such, detection performance (such as that for blood oxygen concentration measurement) and utilization of a photodiode can be improved.

### BRIEF DESCRIPTION OF THE DRAWINGS

FIG. 1A is a schematic view showing a photodiode according to an embodiment of the present invention, wherein an antireflection layer is in contact with a first semiconductor section and a distributed Bragg reflection layer is in contact with a second semiconductor section;

FIG. 1B is a schematic view showing a photodiode according to another embodiment of the present invention, wherein an antireflection layer is in contact with a second semiconductor section and a distributed Bragg reflection layer is in contact with a first semiconductor section;

FIG. 2A is a schematic view illustrating reception of light by the photodiode of the embodiment shown in FIG. 1A;

FIG. 2B is a schematic view illustrating reception of light by the photodiode of the embodiment shown in FIG. 1B; and

FIG. 3 is a plot of reflection rate of the photodiode according to an embodiment of the present invention for light having wavelength in the range of 300 nm-1200 nm.

### DETAILED DESCRIPTION OF THE PREFERRED EMBODIMENTS

Details and technical contents of the present invention will be illustrated below with reference to the attached drawings. However, the drawings are provided for illustration and reference only for the purpose of better understanding of the present invention, and are not intended to limit the scope of the present invention.

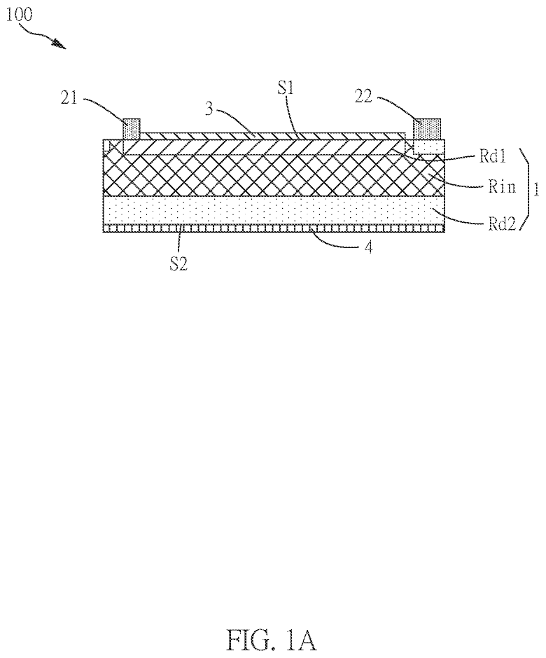

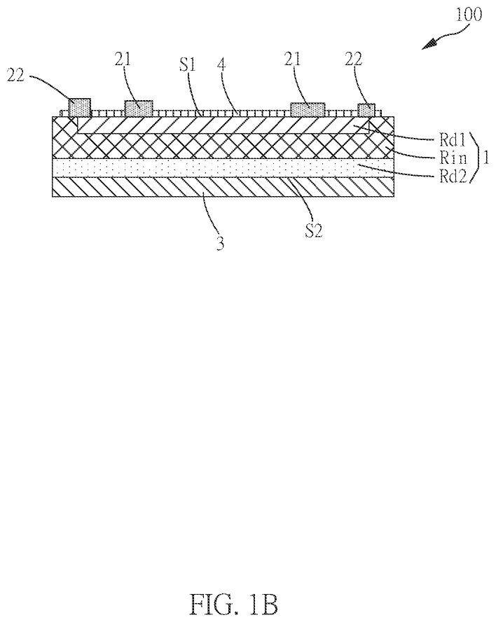

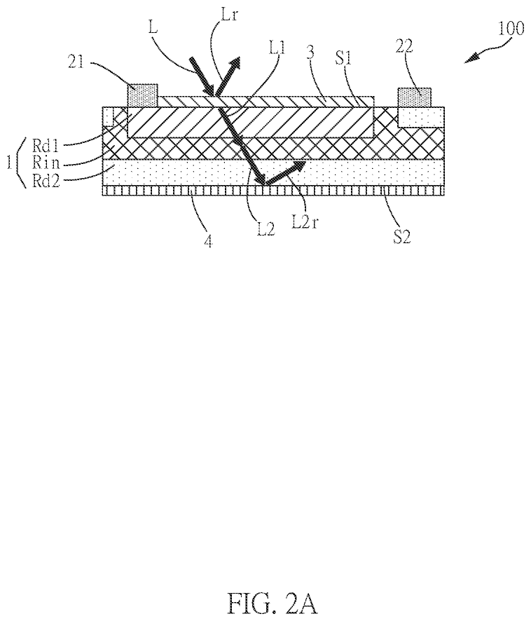

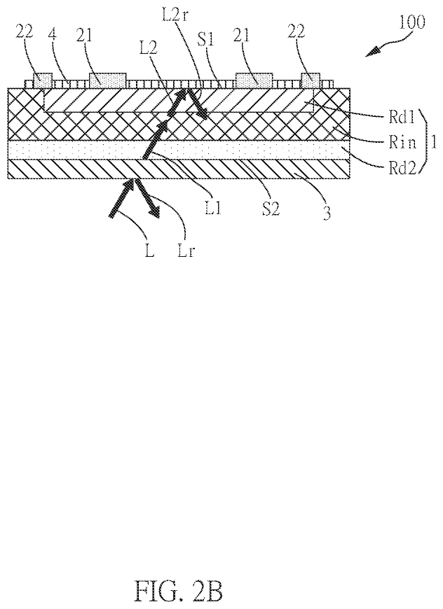

Referring to FIGS. 1A-2B, a photodiode 100 comprises: a light absorption substrate 1, a first electrode portion 21, a second electrode portion 22, an antireflection layer 3, and a distributed Bragg reflection layer 4.

The light absorption substrate 1 includes a top surface S1 and a bottom surface S2 that are opposite to each other. The light absorption substrate 1 includes a first semiconductor section Rd1 and a second semiconductor section Rd2, and a third section Rin. The first semiconductor section Rd1 and the second semiconductor section Rd2 are individually in contact with the third section Rin, and the first semiconductor section Rd1 and the second semiconductor section Rd2 are isolated from each other by the third section Rin. In the instant embodiment, the light absorption substrate 1 is a silicon substrate.

The first semiconductor section Rd1 and the second semiconductor section Rd2 are of opposite conductivity types and are doped with impurities of opposite conductivity types, respectively. For example, the first semiconductor section Rd1 is doped with a donor impurity (such as periodic table group VA elements) to form an n-type semiconductor, and the second semiconductor section Rd2 is doped with an acceptor impurity (such as periodic table group IIIA elements) to form a p-type semiconductor. Alternatively, the second semiconductor section Rd2 is doped with a donor impurity to form an n-type semiconductor, and the first semiconductor section Rd1 is doped with an acceptor impurity to form a p-type semiconductor. The third section Rin is a lightly-doped section.

The first electrode portion 21 is in contact with the first semiconductor section Rd1, and the second electrode portion 22 is in contact with the second semiconductor section Rd2. The photodiode 100 is connectable through the first electrode portion 21 and the second electrode portion 22 to a circuit or for receiving an external voltage. Materials of the first electrode portion 21 and the second electrode portion 22 for example metallic or alloy materials that form ohmic contacts with the first semiconductor section Rd1 and the second semiconductor section Rd2 and are electrically conductive. The first electrode portion 21 and the second electrode portion 22 can be formed through various ways, such as vapor deposition, sputtering deposition, and electroplating. The first electrode portion 21 and the second electrode portion 22 can each be a continuous pattern. The first electrode portion 21 and the second electrode portion 22 can be arranged on the same side or different sides of the light absorption substrate 1. In the embodiments of the present invention illustrated in the drawings, the first electrode portion 21 and the second electrode portion 22 are both arranged on the top surface S1. The second electrode portion 22 can be set in contact with the second semiconductor section Rd2 by means of a via (wherein the via is not located in the cross sections of the present invention illustrated in the drawings, and thus, is not shown in the drawings).

The antireflection layer 3 and the distributed Bragg reflection layer 4 are individually arranged on the top surface S1 or the bottom surface S2 to be individually in contact with the first semiconductor section Rd1 or the second semiconductor section Rd2. The photodiode 100 uses the surface on which the antireflection layer 3 is arranged to form a light receiving surface and a front surface (the top surface S1) or a rear surface (the bottom surface S2) of the dice (the light absorption substrate 1) can be used to receive light. As shown in FIGS. 1A and 2A, the antireflection layer 3 is arranged on the top surface S1 and in contact with the first semiconductor section Rd1, and the distributed Bragg reflection layer 4 is arranged on the bottom surface S2 and in contact with the second semiconductor section Rd2. Or, alternatively, it is also possible that, as shown in FIGS. 1B and 2B, the antireflection layer 3 is arranged on the bottom surface S2 to be in contact with the second semiconductor section Rd2, and the distributed Bragg reflection layer 4 is arranged on the top surface S1 and in contact with the first semiconductor section Rd1.

As shown in FIGS. 2A and 2B, the antireflection layer 3 is arranged to receive light L and allows the light L to get into the light absorption substrate 1. When the light L passes through the antireflection layer 3 to get into the light absorption substrate 1, a portion (<1%) of the light Lr is reflected by the antireflection layer 3. In the instant embodiment, light L1 that gets into the light absorption substrate 1 is absorbed in a light absorption zone of the light absorption substrate 1 to generate a photocurrent. The distributed Bragg reflection layer 4 is arranged to reflect light L2 that has transmitted through the light absorption substrate 1 to exit through the light absorption substrate 1 back into the light absorption substrate 1, namely light L2r. It is noted that the angles of the light shown in the drawings are simply provided in a schematic form and are not drawn to scale according to the refractive indexes of the media through which the light actually travel. Since the light L2r is reflected back into the light absorption substrate 1 to reduce optical loss, the photocurrent and the spectrum sensitivity of the photodiode 100 are enhanced.

A material of the antireflection layer 3 can be silicon nitride (SiNx), and can be formed on the light absorption substrate 1 by means of plasma-enhanced chemical vapor deposition (PECVD).

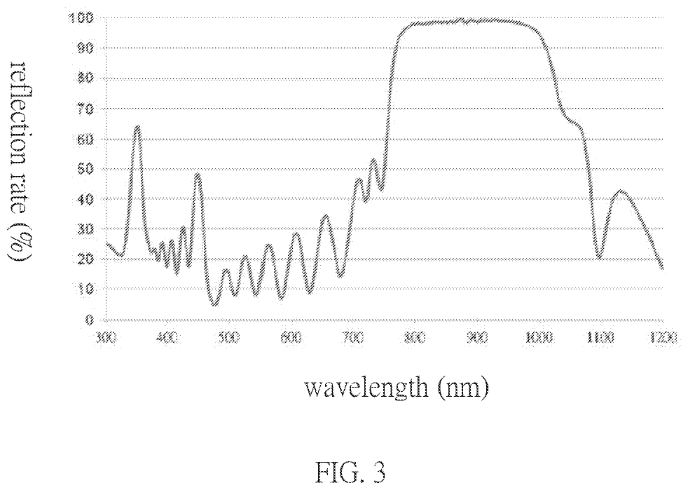

In the instant embodiment, the distributed Bragg reflection layer (distributed Bragg reflector) 4 is formed by stacking multiple layers of dielectric material films. In a preferred embodiment, the distributed Bragg reflection layer 4 has a thickness of 2 μm to 30 μm. FIG. 3 demonstrates reflection rate of the photodiode 100 of an embodiment of the present invention for light having wavelength in the range of 300 nm-1200 nm. In the embodiment, the distributed Bragg reflection layer 4 has a thickness of 3 μm, and the reflection rate for an infrared waveband of 900 nm to 1000 nm may reach as high as 951 to 990. Thus, the photocurrent and the spectrum sensitivity of the photodiode 100 can be further enhanced for such a waveband.

The above description is provided only for some preferred embodiments of the present invention and should not be construed to limit the scope of the claims of the present invention. Equivalent variations and modifications that can be readily achieved based on the disclosure and the drawings of the present invention are considered falling in the scope of the present invention defined by the claims.

What is claimed is:

1. A photodiode, comprising:
a light absorption substrate, the light absorption substrate comprising a top surface and a bottom surface that are opposite to each other, the light absorption substrate being comprising a first semiconductor section, a second semiconductor section, and a third section, the first semiconductor section and the second semiconductor section being individually in contact with the third section, the first semiconductor section and the second semiconductor section being isolated from each other by the third section, the first semiconductor section and the second semiconductor section being of opposite conductivity types;
an antireflection layer; and
a distributed Bragg reflection layer, which is formed by stacking multiple layers of dielectric material films;
wherein the antireflection layer is arranged on the top surface and in contact with the first semiconductor section, and the distributed Bragg reflection layer is arranged on the bottom surface to be in contact with the second semiconductor section, or
the antireflection layer is arranged on the bottom surface and in contact with the second semiconductor section, and the distributed Bragg reflection layer is arranged on the top surface and in contact with the first semiconductor section; and
wherein the antireflection layer is arranged to receive light to get into the light absorption substrate, and the distributed Bragg reflection layer is arranged to reflect light that transmits through the light absorption substrate to exit from the light absorption substrate back to the light absorption substrate.

2. The photodiode according to claim 1, wherein the first semiconductor section is a p-type semiconductor, and the second semiconductor section is an n-type semiconductor.

3. The photodiode according to claim 1, wherein the first semiconductor section is an n-type semiconductor, and the second semiconductor section is a p-type semiconductor.

4. The photodiode according to claim 2, wherein the distributed Bragg reflection layer has a thickness of 2 μm to 30 μm.

5. The photodiode according to claim 3, wherein the distributed Bragg reflection layer has a thickness of 2 μm to 30 μm.

6. The photodiode according to claim 2, wherein the antireflection layer comprises silicon nitride.

7. The photodiode according to claim 3, wherein the antireflection layer comprises silicon nitride.

8. The photodiode according to claim 4, wherein the thickness of the distributed Bragg reflection layer is 3 μm.

9. The photodiode according to claim 5, wherein the thickness of the distributed Bragg reflection layer is 3 μm.
